(19) United States
(12) Patent Application Publication
(10) Pub. No.: US 2012/0156885 A1
(43) Pub. Date: Jun. 21, 2012

(54) METHOD AND SYSTEM FOR PROCESSING SEMICONDUCTOR WAFER

(75) Inventors: Chang-Hsiao LEE, Shanhua Township (TW); Yu-Tsung Lai, Fengyuan City (TW); Jiunn-Hsiung Liao, Shanhua Township (TW)

(73) Assignee: UNITED MICROELECTRONICS CORP., Hsinchu (TW)

(21) Appl. No.: 12/974,714

(22) Filed: Dec. 21, 2010

(51) Int. Cl. H01L 21/465

(52) U.S. Cl. 438/706; 156/345.31; 257/E21.485

(57) ABSTRACT

In a method for processing a semiconductor wafer formed with a copper conductor, the semiconductor wafer is etched in an etching chamber to expose the copper conductor. The etched semiconductor wafer is transmitted from the etching chamber to a buffer zone, where a gas inert to the semiconductor wafer is introduced for a period of time. Then the semiconductor wafer is moved out of the buffer zone to a loading module. Nitrogen is one of the suitable options as the gas, and argon is another option.

### BACKGROUND

1. Technical Field

The present invention relates to method and system for processing a semiconductor wafer, and more particularly to method and system for processing a semiconductor wafer formed with a copper conductor.

2. Description of the Related Art

With the development of semiconductor manufacturing techniques to a sub-micron level, the manufacturing process of an aluminum conductor (hereinafter, “aluminum process”) is subject to RC delay. Nowadays, manufacturing processes of copper conductors (hereinafter, “copper process” or “copper processes”) take the place of the aluminum process in the art due to improved conductivity of copper for current. Therefore, fewer and thinner conductor metal layers are required in a copper process, compared to an aluminum process. Consequently, more chips may be accommodated in a wafer.

However, it is not easy to practice a copper process in a production line of wafers because a lot of problems and challenges having not been encountered in an aluminum process are likely encountered in a copper process. For example, copper is highly active with the presence of air and water, resulting in oxidation of copper. As shown in FIG. 1, after the copper conductor 10 is formed with contact holes 11 and contact plugs 12 subsequently formed thereon, the copper conductor portion disposed under the contact hole 11 (or a via hole in other examples) is likely subject to lateral loss. According to the TEM (Transmission Electron Microscope) pattern, losses of copper conductor 10 under the contact hole and contact plug is rendered with left lateral loss of 22.1 nm from the left wall of the contact plug, right lateral loss of 67.9 nm from the right wall of the contact plug, and vertical loss of 24.1 nm from the original surface of the copper conductor layer. The lateral loss of copper would adversely affect the yield of manufactured wafers.

### BRIEF SUMMARY

Therefore, the present invention provides method and system for processing a semiconductor wafer to reduce lateral loss of copper.

The present invention provides a method for processing a semiconductor wafer. The method is used with a semiconductor manufacturing system. The semiconductor wafer is formed with a copper conductor. The method includes: etching the semiconductor wafer in an etching chamber to expose the copper conductor; transmitting the etched semiconductor wafer from the etching chamber to a buffer zone, where a gas inert to the semiconductor wafer is introduced for a period of time; and moving the semiconductor wafer out of the buffer zone to a loading module.

Preferably, the gas is a boosting gas introduced to increase a gas pressure of the buffer zone from a level matching with a gas pressure in the etching chamber, e.g. 200 mTorr, to a higher level, e.g. an ambient pressure.

Preferably, the gas is a purging gas and inactive to any reaction of the semiconductor wafer.

Preferably the gas is nitrogen or Argon.

The present invention further provides a system for processing a semiconductor wafer. The semiconductor wafer is formed thereon a copper conductor which becomes exposed as a result of an etching process performed in an etching chamber. The system includes: a buffer zone communicable with the etching chamber for accommodating the semiconductor wafer before entering and after leaving the etching chamber; and a gas supply communicable with the buffer zone for supplying a purging gas, e.g. nitrogen or argon, which is inert to the semiconductor wafer and inactive to oxidation of the semiconductor wafer to the buffer zone for a period of time.

Preferably, the gas pressure in the buffer zone is adjustable with different steps. For example, the gas pressure in the buffer zone matches with the gas pressure in the etching chamber upon the semiconductor wafer is entering and leaving the etching chamber, and the gas pressure in the buffer zone is increased to an ambient pressure before the semiconductor wafer is moved out of the buffer zone.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a TEM pattern of a copper conductor layer taken after a contact plug is formed in a contact hole over the copper conductor layer; and

FIG. 2 is schematic diagram illustrating a system for processing a semiconductor wafer according to an embodiment of the present invention.

### DETAILED DESCRIPTION

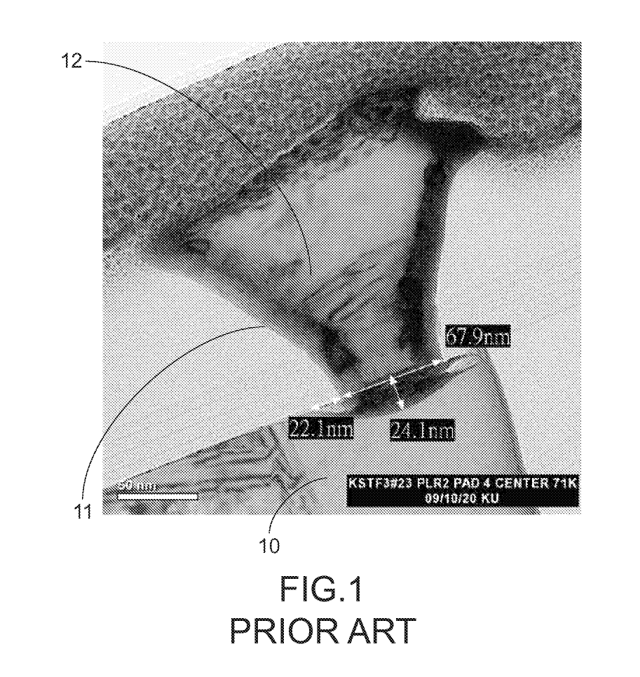

In a dry-etching procedure of a semiconductor wafer, e.g. a dual damascene process performed with a hard mask for forming a contact hole, fluorine is commonly used as an etchant gas. Therefore, after the dry-etching procedure of the semiconductor wafer is completed in an etching chamber containing fluorine so as to expose a copper conductor, the wafer is transmitted outside the etching chamber likely with fluorine adsorbed onto the wafer. During the waiting period for next processing procedure, the remaining fluorine might damage the wafer as fluorine is capable of catalyzing oxidation of copper so that lateral loss as shown in FIG. 1 occurs in a subsequent procedure using deionized water.

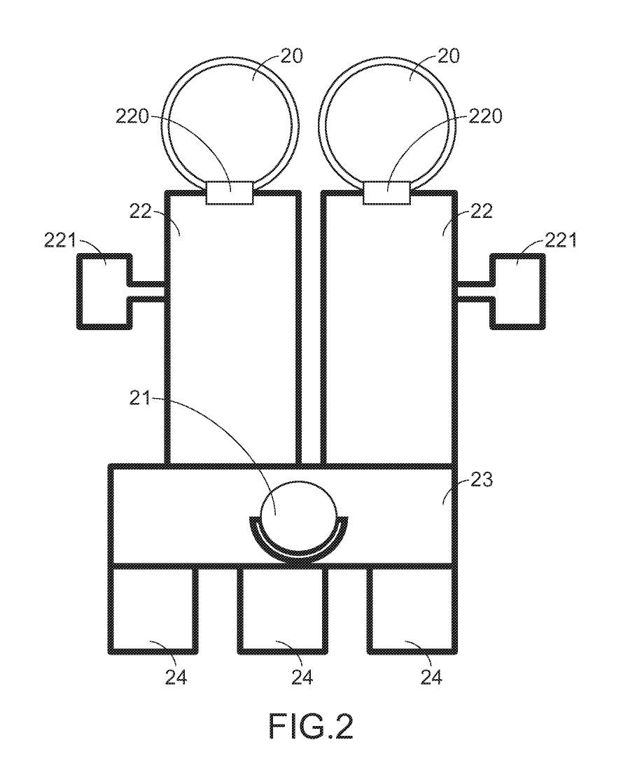

In order to remedy the defects, a system for processing a semiconductor wafer according to an embodiment of the present invention is provided. Please refer to FIG. 2. The system includes an etching chamber 20, where an etching process of a semiconductor wafer 21 formed thereon a copper conductor is performed with fluorine so as to expose the copper conductor (not shown). The etching process, for example, can be a dual damascene process performed with a hard mask. After the etching process, the semiconductor wafer 21 is moved from the etching chamber 20 to a buffer zone 22, where a proper gas pressure is applied in order to adapt the wafer leaving the etching chamber to the ambient pressure. In a preferred embodiment, the buffer zone 22 is also used to accommodate the wafer to be etched before it is transmitted into the etching chamber 20 for etching. In the buffer zone 22, reduction in gas pressure to a certain level matching the order in the etching chamber 20 is performed before the wafer enters the etching chamber 20. In this way, the wafer 21 is adapted to the gas pressure in the etching chamber 20. When the wafer 21 leaves the etching chamber 20 for the buffer zone 22, the gas pressure in the buffer zone 22 remains in the level matching the gas pressure in the etching chamber 20 in order that the valve 220 can be opened for wafer pickup. The gas pressure is then increased to the ambient pressure before the wafer 21 leaves the buffer zone 22 for a loading module 23 and a load port 24 separate from the etching chamber 20. Generally, the gas pressure in the etching chamber 20 is about 200 mTorr.

When the gas pressure in the buffer zone needs to be increased, a boosting gas is introduced into the buffer zone 22 from a gas supply 221 in communication with the buffer zone 22. The boosting gas purges impurity away from the etched wafer. Meanwhile, fluorine adsorbed on the wafer during the etching process can be removed. The gas purge continues for a first period of time. Then the wafer is moved out of the buffer zone 22 and sent to the loading module 23 and then load port 24. The boosting gas is required to be inert to the wafer and inactive to any reaction of the wafer, e.g. oxidation, so as to prevent from damaging wafer while purging the wafer. Nitrogen is one of the preferred options. Basically, the longer the first period of time for purging, the better the purging effect. However, the process time is also increased. Therefore, within the duration of the pressure boosting process, it is desirable that. a long enough period of time is spent in purging.

For comparison, three examples of wafer processing in the buffer zone are performed on the same conditions except different purging time, and the results are summarized in Table 1 based on TEM (Transmission Electron Microscope) patterns taken after the formation of the contact holes and contact plugs over the copper conductor.

TABLE 1

| | Purging Time | Left Lateral Loss | Right Lateral Loss |
|---|---|---|---|
| | (sec) | (nm) | (nm) |
| Example 1 | 30 | 8.3 | ~0 |
| Example 2 | 150 | ~0 | 3.3 |
| Example 3 | 600 | ~0 | ~0 |

It is understood from Table 1 that the lateral loss of copper is largely reduced as the purging time increases, and significantly improved compared to prior art.

To sum up, the copper process can be improved by using a proper purging gas in the buffer zone.

The above description is given by way of example, and not limitation. It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A method for processing a semiconductor wafer, for use in a semiconductor manufacturing system, the semiconductor wafer being formed with a copper conductor comprising:
etching the semiconductor wafer in an etching chamber to expose the copper conductor;
transmitting the etched semiconductor wafer from the etching chamber to a buffer zone, where a gas inert to the semiconductor wafer is introduced for a period of time; and
moving the semiconductor wafer out of the buffer zone to a loading module.

2. The method according to claim 1 wherein the gas is a boosting gas introduced to increase a gas pressure of the butler zone from a level matching with a gas pressure in the etching chamber to a higher level.

3. The method according to claim 2 wherein the gas pressure in the etching chamber is 200 mTorr.

4. The method according to claim 3 wherein the higher level of gas pressure in the buffer zone is an ambient pressure.

5. The method according to claim 1 wherein the gas is a purging gas and inactive to any reaction of the semiconductor wafer.

6. The method according to claim 1 wherein the gas is nitrogen or argon.

7. The method according to claim 1 wherein the etching process is a dry-etching process to form a contact/via hole so as to expose the copper conductor.

8. The method according to claim 1 further comprising transmitting the semiconductor wafer from the buffer zone under a specified gas pressure to the etching chamber to perform the etching step.

9. The method according to claim 8 wherein the specified gas pressure matches with the gas pressure in the etching chamber.

10. A system for processing a semiconductor wafer, the semiconductor wafer being formed thereon a copper conductor which becomes exposed as a result of an etching process performed in an etching chamber, the system comprising:
a buffer zone communicable with the etching chamber for accommodating the semiconductor wafer before entering and after leaving the etching chamber; and
a gas supply communicable with the buffer zone for supplying a purging gas inert to the semiconductor wafer and inactive to oxidation of the semiconductor wafer to the buffer zone for a period of time.

11. The system according to claim 10 wherein the gas pressure in the buffer zone is adjustable with different steps.

12. The system according to claim 10 wherein the gas pressure in the buffer zone matches with the gas pressure in the etching chamber upon the semiconductor wafer is entering and leaving the etching chamber.

13. The system according to claim 10 wherein the gas pressure in the buffer zone is increased to an ambient pressure before the semiconductor wafer is moved out of the buffer zone.

14. The system according to claim 10 wherein the gas supply supplies nitrogen or argon gas for the buffer zone.

15. The system according to claim 10 wherein the etching process is a dry-etching process to form a contact/via hole so as to expose the copper conductor.
